(19) United States
(12) Patent Application Publication
(10) Pub. No.: US 2022/0234963 A1
(43) Pub. Date: Jul. 28, 2022

(54) Method for Making Moldable and Cuttable Composite Material for Magnetic Moment Calibration of Samples with Specific Shapes

(71) Applicant: Zhengzhou University, Zhengzhou (CN)

(72) Inventors: Zon-Han Wei, Zhengzhou (CN); Yen-Ya Hsu, Zhengzhou (CN)

(73) Assignee: Zhengzhou University, Zhengzhou (CN)

(21) Appl. No.: 17/155,698

(22) Filed: Jan. 22, 2021

(51) Int. Cl. C04B 40/00; C08J 3/28

(52) U.S. Cl. CPC C04B 40/0007; C08J 3/28

(57) ABSTRACT

A method for making moldable and cuttable composite material for magnetic moment calibration of samples with specific shapes is provided. The method is used to quantify a magnetic moment per unit weight from the moldable and cuttable composite material. The moldable and cuttable composite material is made by a non-magnetic matrix with superparamagnetic particles, paramagnetic particles, or ferromagnetic particles without anisotropy. Then, the moldable and cuttable composite material is shaped and tailored into calibration samples with specific shapes. The method provides a method for making calibration samples with the specific shapes, wherein the calibration samples are easily shaped and tailored to same or similar shapes and sizes as test samples. The method improves an original method for making a standard calibration sample, wherein the original method only used pure nickel ball or high purity palladium wire structure.

### TECHNICAL FIELD

The invention relates to the magnetic moment calibration of magnetic measurement equipment.

### BACKGROUND

The magnetic moment is the basic physical parameter for understanding the magnetic materials. For example, a Superconducting Quantum Interference Device magnetometer (SQUID) or a Vibrating Sample Magnetometer (VSM) is used to measure magnetic materials. The magnetic measurement equipment is firstly calibrated magnetic moment through a calibration sample with a known magnetic moment. It will cause calibration error in the magnetic measurement equipment if the calibration samples do not have the same or similar shapes and sizes as the test samples.

At present, the high purity palladium wire structure and the pure nickel ball are used as the standard sample for magnetic moment calibration of Superconducting Quantum Interference Device Magnetometer (SQUID) and Vibrating Sample Magnetometer (VSM), respectively. However, due to the complicated metalworking process of pure palladium and nickel, it is difficult to change the shapes of calibration samples for different user's needs. It is also not practical to make a unique shape of the calibration sample for each test sample, so it can be improved by providing a method for making moldable and cuttable composite material for magnetic moment calibration of samples with specific shapes.

### SUMMARY

Unlike the prior art, a new method for making moldable and cuttable composite material for magnetic moment calibration of samples with specific shapes is provided by this invention. This method uses the composite material made by a non-magnetic matrix with superparamagnetic particles, paramagnetic particles, or ferromagnetic particles without anisotropy. First, the magnetic moment per unit weight of the composite material is quantified. Then, the same composite material can be shaped and tailored into the calibration samples with specific shapes. It can avoid the calibration error caused by the different shapes and sizes between the test samples and the calibration samples.

To achieve the above purposes, the invention provides a method for making moldable and cuttable composite material for magnetic moment calibration of samples with specific shapes, it includes the following steps:

S1: The composite material is made by a non-magnetic matrix with superparamagnetic particles, paramagnetic particles, or ferromagnetic particles without anisotropy.

S2: The same composite material is shaped to be a spherical sample. Measure the total weight and magnetic moment of this spherical sample. Finally, the magnetic moment per unit weight of the composite material is quantified.

S3: The same composite material can be shaped and tailored into the calibration samples with specific shapes.

S4: The measured magnetic moment per unit weight is multiplied by the calibration samples' weight to get the total magnetic moment.

S5: The calibration sample is used for instrumentation calibration of the magnetic moment measurement with a specific shape.

Preferably, in step S1, Superparamagnetic or paramagnetic particles or ferromagnetic particles without anisotropy are composed of micron/nano-sized solid powder or liquid. In this way, the magnetic moment of composite material or calibration sample is aligned in the direction of external magnetic field.

Preferably, in step S1, a non-magnetic matrix is polymer materials, cement, gypsum, clay, or other moldable materials.

Preferably, the calibration samples in step S3 have the same or similar shapes and sizes as the test samples from molding and tailoring.

Preferably, the calibration samples with specific shapes in step S3 are spherical, disk-shaped thin film, square thin film, rectangular thin film, triangular thin film, cylindrical, triangular cylinder, cube, cuboid or other arbitrary shapes.

Preferably, in step S5, the positioning and placing of the calibration samples shall be the same or similar to the test samples during the calibration and measurement process.

Compared with the existing technology, this invention solves the magnetic moment measurement inaccuracy caused by the different shapes and sizes between the test samples and the calibration samples. In this invention, the composite material is made by the non-magnetic matrix with superparamagnetic particles, paramagnetic particles, or ferromagnetic particles without anisotropy. The composite material is then shaped and tailored into the calibration samples with the same or similar shapes and sizes as the test samples. Next, by using the calibration samples for instrumentation calibration of the magnetic moment measurement with specific shapes, this invention can avoid the magnetic measurement equipment's calibration error caused by different shapes, sizes and positioning between the test samples and the calibration samples.

### BRIEF DESCRIPTION OF THE DRAWINGS

FIG. 1 shows the results of the elliptical thin film as a test sample. The magnetic moment per unit weight is the Y-axis, and the applied magnetic field is X-axis.

FIG. 2 shows that the magnetic moment per unit weight results from the same composite material are still different from shape and positioning.

FIG. 3 illustrates calibration accuracy verse different shapes of samples on VSM equipment.

### DETAILED DESCRIPTION OF THE EMBODIMENTS

The invention is fully described below in the light of specific examples. At present, the Superconducting Quantum Interference Device magnetometer (SQUID), or Vibrating Sample Magnetometer (VSM), is used to measure the fundamental physical parameters of magnetic materials, hereinafter collectively referred to as the magnetic measurement equipment. In using magnetic measurement equipment, there are errors between the single standard calibration sample and various test samples. A new method for making moldable and cuttable composite material for magnetic moment calibration of samples with specific shapes is used to calibrate the magnetic measurement equipment. The accurate magnetic moment of the test sample can be obtained through a calibration sample with a known magnetic moment.

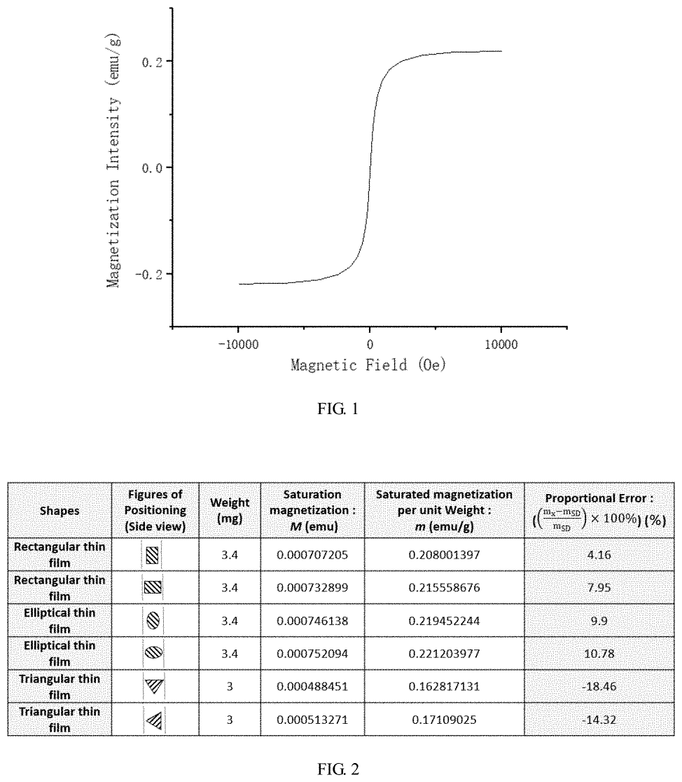

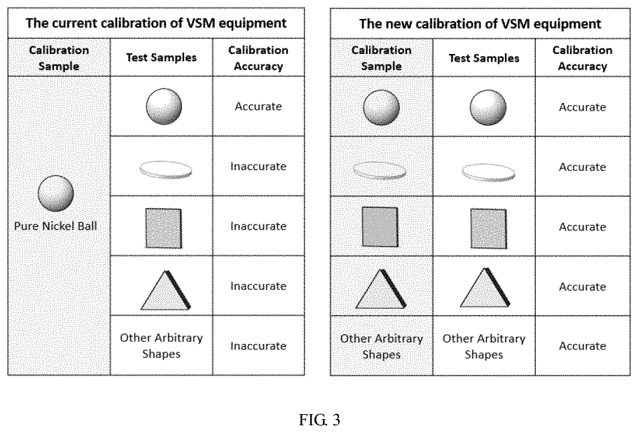

Through the measurement results, the calibration error mentioned above has been confirmed. By using S1, S2 and S3 steps, elliptical, rectangular, and triangular thin films were prepared, and the hysteresis loops were measured by a calibrated Superconducting Quantum Interference Device magnetometer (SQUID). The measurement results were obtained from six different conditions of test samples. FIG. 1 shows the measurement results of the elliptical thin films as a test sample. To be better compared, each test sample's total magnetic moment was divided by its total weight. The magnetic moment per unit weight qualified from the saturation magnetization of the hysteresis loop was excluded from the influence of the weight difference. However, the magnetic moment per unit weight results from the same composite material were still different, as shown in FIG. 2. In our results, the magnetic moment per unit weight was related to the different shape and positioning between the calibration samples and the test samples.

Therefore, the accurate calibration is determined by whether the shape and size of calibration samples and test samples are the same or not. To solve the above problems, the calibration sample can be improved by shaping and tailoring the composite material made of superparamagnetic particles. The superparamagnetic particles were uniformly dispersed in a non-magnetic matrix such as polymer materials, cement, gypsum, clay, etc. The calibration samples with specific shapes could improve the measurement accuracy. Specifically, in this invention, the composite material is made by the non-magnetic matrix with superparamagnetic particles, paramagnetic particles, or ferromagnetic particles without anisotropy. The composite material is then shaped and tailored into the calibration samples with the same or similar shapes and sizes as the test samples. Next, by using the calibration samples with specific shapes for instrumentation calibration, the accurate magnetic moment of the test samples can be obtained. The calibration error caused by different shapes, sizes, and positioning between the test samples and the calibration samples can be avoided. Thus, a method for making moldable and cuttable composite material for magnetic moment calibration of samples with specific shapes is disclosed by the invention.

The specific process of operating the calibration of the magnetic moment is as follows:

S1: The composite material is made by a non-magnetic matrix with superparamagnetic particles, paramagnetic particles, or ferromagnetic particles without anisotropy. Superparamagnetic or paramagnetic particles or ferromagnetic particles without anisotropy are composed of micron/nano-sized solid powder or liquid. In this way, the magnetic moment of the composite material or calibration sample is aligned in the direction of an external magnetic field. Non-magnetic matrix is polymer materials, cement, gypsum, clay, or other moldable materials. The embodiment preferably uses polymer materials as an example.

S2: The same composite material is shaped to be a spherical sample. Measure the total weight and magnetic moment of this spherical sample. Finally, the magnetic moment per unit weight of the composite material is quantified.

S3: The same composite material can be shaped and tailored into the calibration samples with specific shapes. The shapes are spherical, disk-shaped thin film, square thin film, rectangular thin film, triangular thin film, cylindrical, triangular cylinder, cube, cuboid, or other arbitrary shapes. Particularly, the calibration samples must have the same or similar shapes and sizes as the test samples from molding and tailoring.

S4: The measured magnetic moment per unit weight is multiplied by the calibration sample's weight to get the total magnetic moment.

S5: The calibration sample is used for instrumentation calibration of the magnetic moment measurement with a specific shape. The positioning and placing of the calibration samples shall be the same or similar to the test samples during the calibration and measurement process.

The invention described preferred embodiments and their effects. However, once those skilled in the art have learned the basic creative concept, they may make additional changes and modifications to these embodiments. Therefore, the appended claims are intended to be interpreted as including preferred embodiments and all changes and modifications falling within the invention's scope.

Although the embodiments of the invention have been shown and described, it can be understood to ordinary technicians in the art that a variety of changes, modifications, substitutions, and modifications can be made to these embodiments without departing from the principle spirit of the invention. The appended claims and their equivalents limit the scope of the invention.

What is claimed is:

1. A method for making a moldable and cuttable composite material for a magnetic moment calibration of calibration samples with specific shapes, wherein the moldable and cuttable composite material is made by a non-magnetic matrix with superparamagnetic particles, paramagnetic particles, or ferromagnetic particles without an anisotropy; the method comprises:
quantifying a magnetic moment per unit weight of the moldable and cuttable composite material, and shaping and tailoring the moldable and cuttable composite material into the calibration samples with the specific shapes.

2. The method according to claim 1, comprising the following steps:
S1: making the moldable and cuttable composite material by the non-magnetic matrix with the superparamagnetic particles, the paramagnetic particles, or the ferromagnetic particles without the anisotropy;
S2: shaping the moldable and cuttable composite material to be a spherical sample, measuring a total weight and a magnetic moment of the spherical sample, and quantifying the magnetic moment per unit weight of the moldable and cuttable composite material;
S3: shaping and tailoring the moldable and cuttable composite material into the calibration samples with the specific shapes;
S4: multiplying the magnetic moment per unit weight by a weight of a calibration sample of the calibration samples to obtain a total magnetic moment; and
S5: performing an instrumentation calibration of a magnetic moment measurement with a specific shape by using the calibration sample.

3. The method according to claim 2, wherein in step S1, the superparamagnetic particles or the paramagnetic particles or the ferromagnetic particles without the anisotropy are composed of a micron/nano-sized solid powder or liquid, wherein a magnetic moment of the moldable and cuttable composite material or the calibration sample is aligned in a direction of an external magnetic field.

4. The method according to claim 2, wherein the non-magnetic matrix in step S1 is polymer materials, cement, gypsum, clay or other moldable materials.

5. The method according to claim 2, wherein the calibration samples in step S3 have same or similar shapes and sizes as test samples from shaping and tailoring.

6. The method according to claim 2, wherein the calibration samples with the specific shapes in step S3 are spherical, disk-shaped thin film, square thin film, rectangular thin film, triangular thin film, cylindrical, triangular cylinder, cube, cuboid or other arbitrary shapes.

7. The method according to claim 2, wherein the calibration sample is configured for the magnetic moment calibration in step S5, the calibration samples are positioned and placed in a same or similar manner as the test samples during a calibration and measurement process.
